(19) United States
(12) Patent Application Publication
(10) Pub. No.: US 2009/0014053 A1
(43) Pub. Date: Jan. 15, 2009

(54) Process for the energy conversion of solar radiation into electric power and heat with colour-selective interference filter reflectors and a concentrator solar collector with colour-selective reflectors as an appliance for applying this process

(76) Inventor: Detlef Schulz, Leipzig (DE)

Correspondence Address: COLLARD & ROE, P.C., 1077 NORTHERN BOULEVARD, ROSLYN, NY, 11576, US

(21) Appl. No.: 10/587,797

(22) PCT Filed: Jan. 29, 2005
(86) PCT No.: PCT/EP05/00889

§ 371 Date: Jul. 31, 2006

(30) Foreign Application Priority Data
Jan. 30, 2004 (DE) 10 2004 005050.3

(51) Int. Cl. H01L 31/052; H01L 31/058; H01L 31/0216; F24J 2/06

(52) U.S. Cl. 136/246; 136/248; 136/259

(57) ABSTRACT

The invention relates to a method and a device for a concentrator/solar collector for splitting solar radiation into various spectral colours by means of colour-selective mirrors, and for concentrating the same onto a plurality of semiconductor-photovoltaic cells optimised for various light colours. The inventive device is used to convert the energy of the solar radiation into an electrical current and heat with a high efficiency.

The invention concerns a process and a concentrator solar collector as the associated appliance to split up solar radiation with the help of colour-selective reflectors into several spectral colours and to concentrate this radiation in photovoltaic cells made of semi-conductors that have been optimised for different light colours. The invention is aimed at converting the energy of solar radiation into electric power and heat with a high efficiency.

There are already different solar radiation collectors and energy converters in existence. Thermal solar collectors converting the collected solar radiation into heat are widely used for air-conditioning. This form of energy warms up a carrier medium (water, oil, gas, etc.) and can be combined with thermo-dynamic working cycles, such as heat pumps, Stirling engines and Rankine cycles. This indirect conversion of the energy-rich solar radiation via heat with its high energy potential “back” into energy-rich electric power causes high losses (because it is a detour) and is basically limited by the Carnot coefficient. In order to achieve high temperatures, concentrator technologies, such as concave reflectors (collecting mirrors) or Fresnel reflector panels are necessary that can only use direct radiation but no diffuse light in cloudy weather. Therefore, solar power plants for the generation of electric power are usually only economically viable, when there is a lot of sunshine at their location. The light is directly converted into electric power with semi-conductor “photocells”. As a matter of principle, the individual materials for the semi-conductors or combinations thereof are only suitable for certain spectral ranges of the collected solar radiation. Hence, a large share of the radiation energy cannot be used for the generation of power. This share will be turned into heat and any temperature rise will also increase the recombination losses in the semi-conductors during the photovoltaic energy conversion. Flat collectors made of polycrystalline silicon have been most widely used in the market for large-size applications. Their efficiency ranges typically between 12 and 17% and they can use both direct and diffuse light. Apart from silicon, further materials are known to be used for semi-conductors, which have a high quantum efficiency for certain light colours. Among these count especially GaAs, CdTe, GaInP, InP, GaInN, CuS₂, CuInS₂, CuIn(GaSe)₂, Ge, CdSe, a—Si:H and various alloys with 4 and more alloy elements, especially with contents of elements of the 3^{rd} and 5^{th} main group. The manufacture of many of these alloys is relative expensive as compared with that of Si. The production costs of solar power generated in this way have so far not been able to compete with the generation costs of other energy sources. In this respect, thin-film technologies promise cost-reduction potentials, as do micro-porous dye sensitized cells (DSC) and quantum-dot structures, such as the Graetzel cell. The loss mechanisms in the individual semi-conductor materials known to be used for solar cells can hardly be optimised any further because they are predetermined in a physical sense by the material used. This will result in a theoretical efficiency of, say, 27% the most in the case of silicon with the highest degree of purity. Layered systems of semi-conductor materials with different band gaps for the use of larger spectral ranges as well as nano-porous layered systems may allow an even higher array packing efficiency (cell packing factor). Further cost optimisation potentials are concentrator technologies. Instead of using relative expensive large semi-conductor areas, attempts have been made to focus the light with inexpensive optical components, such as lenses or concave reflectors, in order to light smaller, but highly efficient semi-conductor surfaces with a highly concentrated luminous intensity. Although this is a way to drastically reduce the costs of semi-conductors per surface area to be covered and per Watt generated, the concentrator technologies are hardly suitable for using diffuse radiation, which is a great disadvantage especially in moderate climate regions with a high degree of cloudiness. This requires a particularly high solar cell efficiency so that at least the same annual energy yield can be achieved per surface area as conventional photovoltaic flat cell modules do. Achieving this increased cell efficiency requires the use of tandem cell technology (systems with several different semi-conductor layers) or the conversion of wavelengths that are not used for photovoltaic purposes with the existing photocell semi-conductor into useable ones, such as with photon separator or luminescence layers. The disadvantage with such multiple tandem layers is that the top layers already absorb some of the radiation and turn it into heat or reflect it, although this radiation was supposed to reach the lower layers. Besides, the manufacture of such tandem layers requires several steps, which is a cost factor. Another well-known approach to reducing these losses is the spatial separation of the solar radiation into its light colours. These wavelength ranges of the light thus defined will then be directed at solar cells, which are also spatially separated and made of semi-conductors that are optimised for the relevant light colour. On the other hand, holographic concentrators over a diffraction grating have revealed new sources of losses and problems (absorption and scatter losses as well as the UV-light, aging and moisture resistance of the holograms) and not been able to conquer the market so far. Interference reflectors are much more suitable for this purpose. It has been known for quite a while that interference on thin films can enhance or weaken reflections. Constructive interference is used in dielectric reflectors and optical colour filters as well as in low emissivity glass, in order to enhance the reflection for a required wavelength range. Destructive interference is used for reflection-reducing surfaces so that the degree of transmission achieved is much higher while the absorption remains the same, as is the case with window panes and photo-optical lenses (suppression of reflections). By superimposing many highly transparent dielectric layers and by varying the layer thickness as well as the refractive indices, constructive interference will also make it possible to cover wider spectral ranges and to achieve high degrees of reflection of up to more than 99%. An example are the alternating [symbol] /4 layers of silicon dioxide and tantalum pentoxide that have stood their test as interference reflectors. The production of these interference reflectors by magnetron sputtering in high vacuum as previously done is all the more expensive the more layers are required. These high expenses have not resulted in any cost advantages as compared with the production of tandem cells. Also other transparent materials with a rather different optical refractive index may form such layer systems. Interference reflector films have been made from plastic for a short while now and manufacturing processes using plastic-type organic or inorganic soft glass have been mentioned, in which comparatively inexpensive films are made in a lamination and extrusion process with several hundred [symbol] /4 layers. The problem with such films is their UV-light, aging and moisture resistance as well as the electrostatic chargeability (proneness to contamination) and the mechanical stability so that their use in solar collectors in poor weather conditions has hardly been considered an ideal solution. Iridescent films like that have been found more in the field of packaging where they are used as decorative sheets. Other problems occurring when solar collectors are used are surface contamination and the durability of such interference reflector films under the prevailing weather conditions.

The invention has been aimed at finding suitable interference filter materials and configurations for solar radiation applications that can be manufactured in a cost-effective way and whose proneness to contamination, discolouring or corrosion under the influence of changing temperatures, of humidity (also in the dew point range) and of dust is low.

The mission will be accomplished as follows:

A typical feature of the appliance which is the subject of the invention is that the light will be separated into at least two spectral wavelength ranges with the help of movable interference reflector films, with each of the films reflecting one wavelength range and transmitting another one.

Prior to that, the direct solar radiation will be focused refractively, e.g. with Fresnel lenses, or reflectively, e.g. with concave reflectors or Fresnel concave reflectors (reflector panel). One or several such interference reflector films are placed in front of the focal point, so that there is one focal point for the reflected and also one for the transmitted light fraction. The photo cells installed in the area of these focal points will be made of such semi-conductor materials that have the most optimal efficiency for the relevant wavelength range, when the light radiation is converted into electric power. The colour-selective interference reflectors will be made of film that is scrolled reel by reel slowly like a movie film through the light cone. This has the benefit that inexpensive plastic film laminate can be used for this purpose. Many optically transparent, but inexpensive plastic materials show aging symptoms when exposed to light, especially when exposed to UV-containing solar radiation, they gradually turn yellow, become brittle, lose their stability or shrink. This process can be intensified by moisture and dust and the optical properties of the surface may also be negatively affected. The impairment of the reflector functions by light-induced degradation and contamination can be reliably avoided by continuously renewing the film segments that are exposed to the light cone. This scrolling movement of the film can take weeks, months or years, depending on the material used for the film or on the light intensity. Depending on the length of the film reels, the operating hours thus achieved are also very long and the film reels need not be exchanged or renewed for years. The materials preferably used for the light-transmitting elements of the invented appliance (Fresnel lenses, interference reflector films) should not only have the required visible spectrum, but also a high transparency for NIR radiation of up to approx. 2 μm. Fluorine polymers and fluoride glass allow the sun light to shine through in a wide frequency spectrum. The transparency for UV radiation will reduce the degradation of the film and enhance the energy yield. Thin-layered systems in form of thermoplastic film with transparent base materials made of plastic (PMMA, PC, styrene) with contents of tellurium or fluorine compounds can be used for a wide spectral range, right up to the near infra-red range (NIR). Two plastic films with a different refractive index each will be laminated several times on top of each other in the softening temperature range until the thickness of the individual layers amounts to a quarter of the wavelength to be reflected. The photocells located in the focal points in front of or behind the interference reflector films will be exposed to a high illuminance, typically ranging between the 50-fold and 2500-fold sun concentration. The design of the cells needs to be geared to the expected photoelectric current (concentrator cells). When the band gap of the semi-conductor is properly adjusted to the relevant light colour range, the quantum efficiency of the photovoltaic conversion will be high and the heat generation proportionally lower. Any heat still generated will have to be discharged, for which a water cooling system could be used. The photocells will therefore be installed on a heat sink through which a cooling medium can be channeled. Apart from water and watery solutions, organic solving agents, typical coolants (e.g. R134, propane etc.), binary solutions (e.g. ammonia solutions) or, under higher operating pressures, gas (such as helium) can be used for this purpose. Apart from operating heating systems like this, the heat to be discharged may also operate absorption refrigeration plants, organic Rankine cycle systems (ORC systems), Villumier heat pumps and magneto-caloric-effect converters (MCE converters).

A very thin-layered system with a thermionic function made of, say, Bi₂Te₃/Sb₂Te₃ (thermo diode) between the solar cell and the heat sink may partly convert the heat current thus generated into electric power, which would increase the electric efficiency further. A light fraction may also be fed into an optical wave guide (LWL) rather than into a solar cell. This would make it possible to use the blue light of the sun for photo-chemical reactions in a closed reaction vessel, which could also be installed in rooms that are not illuminated.

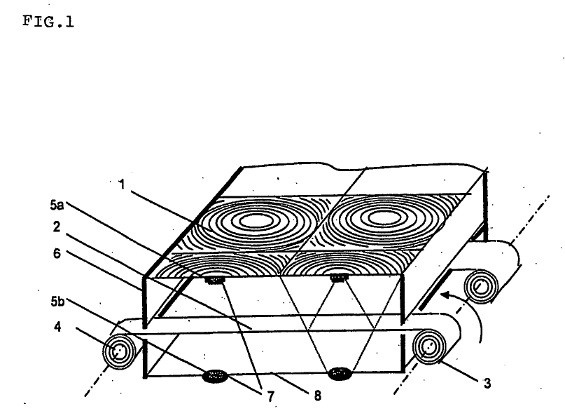

FIG. 1 shows an example of how the invented appliance could be designed with refractive concentrators.

Convex Fresnel lenses 1 are installed in a frame 6 on the upper light-transmitting limiting plate that is exposed to the light. They are aligned always vertically to the sun's position, with the external side of the upper limiting plate preferably being coated with an anti-reflection or easy-to-clean material (dust and water-repellent surface). The lower limiting plate 8 is located underneath and parallel to the upper limiting plate with the Fresnel-lenses 1. Both limiting plates and the side walls of the frame 6 form a more or less dust and water-proof box. The depth of the frame 6, i.e. the distance between the upper Fresnel lens 1 and the lower limiting plate 8, corresponds approximately to the focus of the Fresnel lenses 1 used. Germanium photocells for NIR radiation 5b have been installed precisely in the place, where the focal point of the Fresnel lenses 1 is. The photocells have been attached to heat sinks 7 through which a liquid can be channeled. If the Fresnel lenses 1 are aligned vertically to the sun, a light cone will be formed and the radiation will be focused onto the relevant germanium photocell 5b, which has a much smaller surface for NIR radiation, as compared with the Fresnel lens. The germanium for the semi-conductor has a lower band gap and is particularly efficient in a photocell for NIR radiation of up to 2 μm, but less suitable for visible light. A several meter long interference reflector film 2 in the form of a tape, reeled on a spindle 3 will be installed between the Fresnel lenses 1 and the lower limiting plate 8. This “tape” will be reeled off spindle 3 and wound onto spindle 4 in the course of the appliance's service life, so that the interference reflector film 2 will be pulled slowly through the relevant light cone of the Fresnel lenses 1. The interference reflector film 2 consists of several layers of alternating transparent plastic sheets with a different refractive index, e.g. PMMA and polystyrene that have been put on top of each other. Alternatively, other types of plastic with a better UV-light resistance and NIR transparency may be used as well. The thickness of these plastic layers must range between 88 and 200 nm, so that a high reflection for wavelengths in the VIS range (350-800 nm) is achieved, while the NIR radiation will be transmitted. The distance of this interference reflector film 2 to the Fresnel lenses 1 and to the lower limiting plate 8 is about the same, so that the focal point of the VIS light reflected by the interference reflector film 2 is located shortly before the centre of the Fresnel lens 1 of the upper limiting plate. A silicon photocell for VIS radiation 5a will also be installed in this focal point in the centre of the Fresnel lens 1 on a heat sink 7 through which a liquid is channeled. The silicon of the semi-conductor has a larger band gap than germanium and can be used in a photocell for VIS radiation 5a, but it is unsuitable for NIR radiation from 1.2 μm. Instead of using silicon and germanium, other semi-conductors, such as GaAs, CdTe, GaInP, InP, GaInN, etc., may also be used, as has been mentioned above.

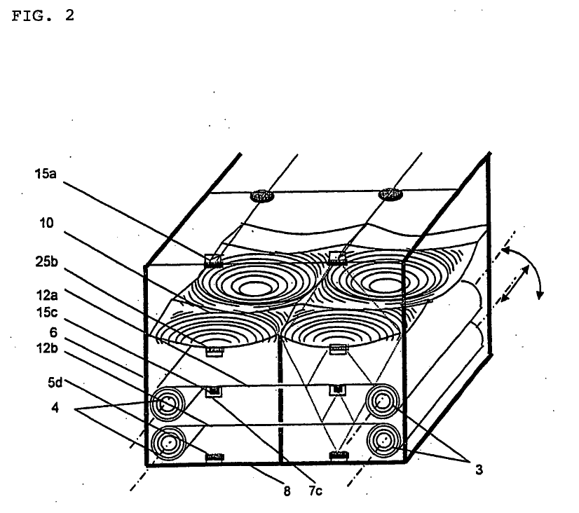

FIG. 2 shows another design of the invention, in which not two but four different wavelength ranges (light colours) are directed at four different photocells. As compared with the design in FIG. 1, this one here makes it possible to achieve a much better electric efficiency. The cover plate is made of glass and coated on the outside with a multi-layered weather-resistant interference reflector layer system made, for instance, of silicon dioxide and tantalum pentoxide with a thickness of 55-110 nm each, which will reflect the UV and blue light and which will transmit green, yellow, red and near infrared radiation contents up to a wavelength of at least 2 μm. The glass plate will be pressed in an arch-like shape and has, on the inside, Fresnel lenses with their typical profile 10 and interference concave reflectors on the front side for the blue light. The arch-like shape of the glass plate with the interference reflector layer system has the function of a concave reflector. If the frame 6 with the Fresnel lenses and the interference concave reflectors for the blue light 10 on the front side is aligned vertically to the sun, the arch-like shape with the interference reflector layer system will form light cones above these concave reflectors with the reflected UV and blue light. Photocells 15a made of InGaP or CdS with a high quantum efficiency for blue and UV radiation will be installed in the focus of each of these concave reflectors. One light cone each of the non-reflected green, yellow, red and NIR contents of the light will be generated under the Fresnel lenses with the interference concave reflectors for blue light on the front side 10, which can be further fractioned with the interference reflector film 2 of the invented appliance. Two different interference reflector films 2 in the form of tapes will be placed on top of each other between the Fresnel lenses with the interference concave reflector for the blue light 10 and the lower limiting plate 8, which will be reeled off spindle 3 and wound onto spindle 4 while passing through the light cone. A relative movement of the interference reflector films 2 within the light cone may also be effected by the axial shift of the spindles 3, 4 in relation to the zone with the highest light concentration, since it can be expected that the films will be less damaged in the light cones' marginal areas by light-induced degradation due the lower radiation concentration and residence time. Once the film has been reeled off spindle 3 onto spindle 4, it can be reeled back to its original spindle 3 after having made an axial shift. This will extend the useful life of the relevant interference reflector film 2 accordingly. While the first interference reflector film for the green and yellow VIS radiation 12a will reflect the wavelength range of approx. 440-650 nm (green and yellow) onto a photocell for green and yellow VIS radiation 25b which has been optimised for this purpose, e.g. a photocell made from GaAs, the second interference reflector film for the red VIS radiation 12b which is located at some distance underneath the first one will be designed for the reflection range between 650 and 1100 nm. In the latter's focus, i.e. between the two interference reflector films 2, a double-sided photocell for red VIS radiation 15c can demonstrate its optimal efficiency. The casing for the cooling liquid for the photocell 15c with the heat sink 5c is preferably transparent for the radiation range of 650-2000 nm, which also applies to the cooling medium. On the other hand, the lower photocells for the NIR radiation 5d at the lower limiting plate 8 are optimised for the NIR radiation of 1.1-2 μm and to could be made of semi-conductors like germanium or InGaAs. Several such frames 6 can be installed on or attached to suitable holders or posts and be equipped with rotary drives that will always align the frames 6 vertically to the current sun position, so that the direct light beams are always focused through the Fresnel lenses with the interference concave reflectors for blue light on their front side 10 onto the photocells.

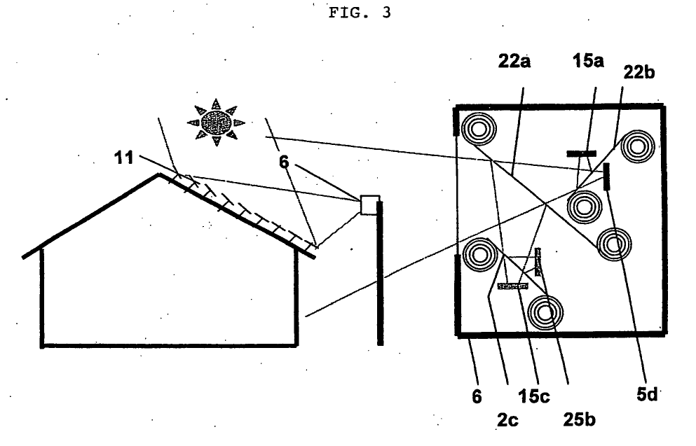

FIG. 3 shows the invented appliance with a reflective concentrator. Here, the solar radiation is concentrated with Fresnel concave reflectors 11. They come as stand-alone reflectors and, located on a roof, on a building's façade or on a free space, are movable so as to be able to follow the sun. The direct solar radiation will be directed at a solar receiver in the form of a frame 6 which is sufficiently protected against the weather conditions and consists of several photocells made from different semi-conductors as well as one or several interference reflector films 2 which are the subject of the invention. These films are reeled off spindle 3 onto another spindle 4, while passing through the light cone generated by the Fresnel concave reflectors 11 when entering the solar receiver or while passing a light cone that has already been reflected from the first interference reflector film for the blue VIS radiation or for the UV and blue VIS radiation 22a. In this design the interference reflector films 2 will be dimensioned in such a way that optimal reflection wavelengths of the individual interference reflector films 22a, 22b, 2c for the relevant photocells 15a, 25b, 15c and 5d are achieved, when the lighting angle is approx. 45°.

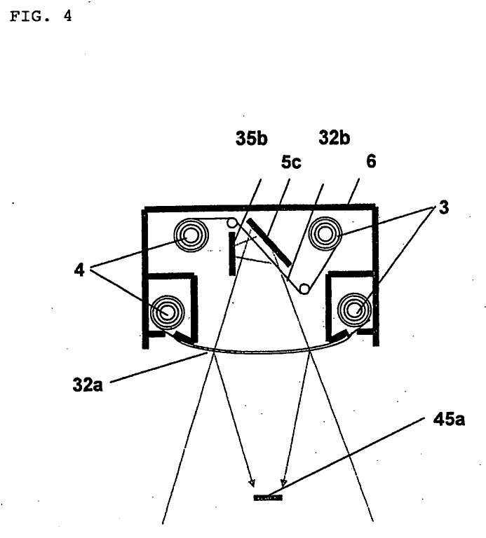

FIG. 4 depicts a solar receiver for the Fresnel concave reflector configuration as shown in FIG. 3. In this case, an interference reflector film for blue and green VIS radiation 32a located in that section of the frame 6 where the light enters the appliance reflects a defined spectral range of the light, e.g. blue, green and yellow, onto a photocell for blue and green VIS radiation 45a that is made from, say, GaAs and is located outside the frame 6. The radiation contents red and NIR that are to be transmitted by the first interference reflector film for blue and green VIS radiation 32a will now be directed at a second interference reflector film for yellow and red VIS radiation 32b which will reflect the red light content onto an Si photocell for yellow and red VIS radiation 35b and will transmit NIR which will hit a germanium photocell for NIR radiation 5c.

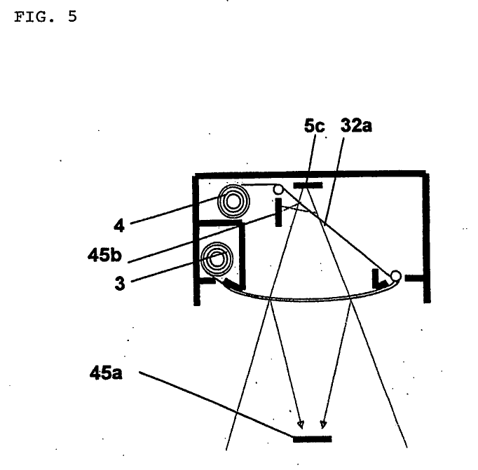

FIG. 5 also depicts a solar receiver for the Fresnel concave reflector configuration as shown in FIG. 3. This configuration takes advantage of the fact that the same interference reflector film for the blue and green VIS radiation 32a reflects another wavelength range when being exposed to radiation at an entry angle of about 0° as would be the case if the radiation angle was flatter, say, about 45°. The thickness of the alternating plastic layers of the interference reflector film for the blue and green VIS radiation 32a, as shown in the design of FIG. 5, ranges between 100 and 132 nm, so that the film will reflect the blue and green light when being exposed vertically to it, while yellow, red and NIR will be transmitted. If the radiation which has initially been transmitted passes the same film again, but at in a much steeper angle of, say, 40°-50°, the yellow light will now be reflected as well, while red and NIR are more or less transmitted once more.

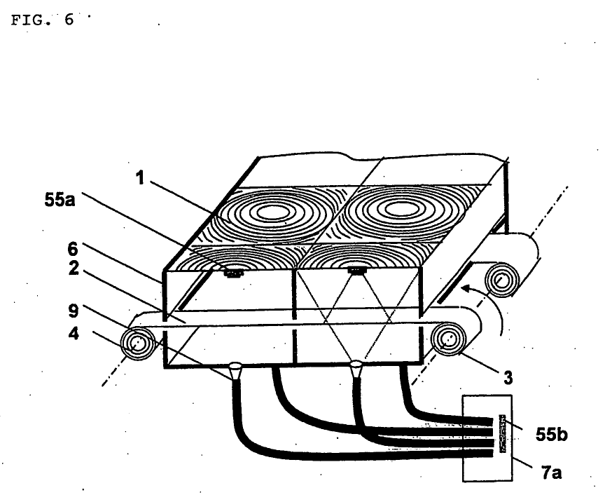

FIG. 6 shows that one or several contents of the light that have been split up with the interference reflector films 2 may also be fed into an optical wave guide 9, e.g. a tube or a hose filled with liquid, rather than in a photocell, and be transported over a limited distance to another place. This application is demonstrated with the design and configuration of the appliance with a refractive light concentrator, as has already been shown in FIG. 1. The focal point of Fresnel lens 1 is located in the sector where the fibre glass enters the appliance, provided it is precisely aligned towards the sun's position. A user-defined number of such optical wave guides 9 will be combined and the radiation can be directed at the other end of these optical wave guides 9 at a photo-chemical reactor, at a photocell for NIR radiation 55b or at any other surface or rooms to be illuminated. This can be highly advantageous, because a photo-reactor may be located in a separate room (heated or heat-insulated) or a photocell may be installed directly in a cooling water reservoir (e.g. a swimming pool). Instead of using optical wave guides (LWL) made of quartz glass, one can also use hoses filled with liquid as LWL, thus reducing the heat losses and simplifying the cooling of the photocells.

The invented appliance distinguishes itself from solar collectors and other devices for feeding light into optical wave guides in as much as the light will be split up into at least two spectral wavelength ranges with the help of movable interference reflector films 2, with each of these interference reflector films 2 reflecting one wavelength range and transmitting one part. The direct solar radiation will be refractively focused prior to that with Fresnel lenses 1 or, reflectively, with concave reflectors or Fresnel concave reflectors 11 (reflector panel). One or several such interference reflector films 2 will be placed in front of the focal point, so that there is one focal point for the reflected and also one for the transmitted light fractions. Photocells made of semi-conductor materials that have the most optimal efficiency for converting the light radiation into electric power in the relevant wavelength range will be placed in the area of these focal points. The interference reflector films 2 serve as colour-selective interference reflectors and are slowly moved through the light cone from one reel to the other via spindles 3 and 4.

The invention offers several advantages.

The concentrator technology is advantageous in as much as the light will be concentrated on very small semi-conductor surfaces with the help of relatively inexpensive optical components (reflectors, Fresnel lenses), thus saving expensive semi-conductor surfaces.

Splitting up the solar radiation into several wavelength ranges (light colours) offers the advantage that several semi-conductor photocells which have been optimised in line with the relevant wavelengths can now be operated with a higher photovoltaic conversion efficiency which, in turn, will improve the electric efficiency as a whole.

Reeling off the interference reflector films 2 slowly with the help of spindles 3 and 4 and passing them through the light cone between the reels has the advantage that any foreign particles that might have accumulated on the film surface or any damage caused by moisture, burnt-in foreign particle and light-induced degradation will not permanently affect the film, since the film sections are continuously replaced through the reeling. These thin interference reflector films 2 can be produced by an inexpensive and large-scale technique from plastic material that is mass-produced in a lamination, rolling or extrusion process. Cost-intensive chemical vapour deposition (CVD) or epitaxial separation techniques in high vacuum are not required.

Besides, movable Fresnel concave reflectors 11 that are integrated into the roof or façade structure as shown in FIG. 3 have the additional benefit that they can be combined with flat-shaped weak light solar surfaces, as the dye sensitized cell (DSC) technology offers. In this case, the Fresnel concave reflectors 11 can be turned under cloudy conditions in such a way that these DSC surface will be optimally exposed to the light. This makes it possible to use both direct and diffuse (scattered) light in a large spectral range, which will considerably increase the annual energy yield.

In addition to that, the noiseless and largely maintenance-free collector surfaces can be optimally integrated into existing residential areas and mounted on buildings, road lanterns and posts, since the collectors need not be joined to each other. They may rather consists of many small, even differently designed shapes and forms, “islands” so to say, whose combined output will achieve a high lighting performance. When suitably dimensioned, the efficiency of the interference reflector films 2 and of the semi-conductor surfaces should be considerably higher than that of conventional photovoltaic systems, provided they are exactly aligned towards the sun. Their higher economic efficiency will also be ensured by the lower investment costs and by the easier selection of a location, as compared with surface-area modules that also use diffuse light.

Feeding light into optical wave guides (LWL) has the advantage that the focused light energy from large surfaces of a defined wavelength range can be transported over a limited distance via a non-linear route and focused on extremely small surfaces. This light may be used for the illumination of window-less rooms inside buildings or rooms in basements. It is also possible to operate plants for the catalytic decomposition of water (hydrogen production), for the biological waste water treatment or for photo-catalytic chemical reactions. The more efficient production of biomass in a photosynthetic process (e.g. the production of algae) will become possible by immersing the fibres in turbid liquids, so that the cumbersome glass-tube structures that are still widely used (and that cannot be heat-insulated) are no longer required. Red and infrared radiation can usually not be used for the photosynthesis, so that this form of radiation can also contribute to the generation of power with the help of the invented appliance. Photosynthesis and power generation are impossible with other feeder devices for optical wave guides.

### Legend

1 Fresnel lenses (refractive light concentrator)
2 interference reflector film
2c interference reflector film for red VIS radiation up to NIR<1100 nm
3 spindle from which the film is reeled off
4 spindle onto which the film is wound
5a silicon photocells for VIS radiation
5b germanium photocells for NIR radiation
5c photocell for NIR radiation e.g. from Ge
5d photocells for NIR radiation
6 frame
7 heat sink
7a heat sink, vessel filled with liquid
7c heat sink of photocell 15c
8 lower limiting plate
9 optical wave guide, e.g. tube/hose filled with liquid
10 Fresnel lenses with interference concave reflectors for blue light on the front side
11 Fresnel concave reflector (reflective light concentrator)
12a interference reflector film for green and yellow VIS radiation
12b interference reflector film for red VIS radiation up to NIR<1100 nm
15a photocells for blue VIS radiation
15c photocells for red VIS radiation up to NIR<1100 nm
22a interference reflector film for blue VIS radiation or UV and blue VIS radiation
22b interference reflector film for green and yellow VIS radiation
25b photocells for green and yellow VIS radiation
32a interference reflector film for blue and green VIS radiation
32b interference reflector film for yellow and red VIS radiation up to NIR 1100 nm
35b photocell for yellow and red VIS radiation up to NIR<1100 nm, e.g. from Si
45a photocell for blue and green VIS radiation, e.g. from GaAs
45b photocell for yellow and red VIS radiation, e.g. from Si
55a photocells for VIS radiation
55b photocell for NIR radiation

1. Process for the conversion of solar radiation into electric power and heat with one or several colour-selective interference filter reflectors that will split up solar radiation into different wavelength ranges and concentrate it on several photovoltaic cells that are made of semi-conductors and that have been optimised for different light colours, wherein the light will be separated into at least two spectral wavelength ranges with the help of movable interference reflector films (2), with every film reflecting one wavelength range and transmitting another part.

2. Process in accordance with claim 1, wherein the direct solar radiation will be concentrated refractively or reflectively before being split up into two or several wavelength ranges and that one or several movable interference reflector films (2) are located as focal points at one or two levels before the area with the highest light concentration so that there will always be one focal point for the light fraction which is reflected by the interference reflector film (2) and also one for the light fraction which is transmitted by the interference reflector film (2), while the geometric position of these focal points does not change at all or only insignificantly by the one or two-dimensional movement of the interference reflector films (2).

3. Process in accordance with claim 1, wherein the interference reflector film (2) cannot only be moved by reeling it off spindle (3) and onto spindle (4), but also by shifting the spindles (3 and 4) axially in relation to the zone with the highest light concentration.

4. Process in accordance with claim 1, wherein the interference reflector film (2) is either continuously or discontinuously re-reeled.

5. Appliance of a concentrator solar collector with colour-selective reflectors, wherein lenses, preferably Fresnel lenses (1), are installed in a given frame (6) of the solar collector and directed towards the sun light, with a photocell being in the focal point of the lens, and that a movable interference reflector film (2) has been installed between the lens and the photocell.

6. Appliance in accordance with claim 5, wherein the colour-selective interference reflector film (2) is made of a flexible foil, with a section of which being slowly be moved from spindle (3) to spindle (4) through the concentrated solar radiation.

7. Appliance in accordance with claim 5, wherein photocells made from such semi-conductor materials with a band gap geared to the relevant wavelength range are located in the area of one or several of these focal points.

8. Appliance in accordance with claim 5, wherein always one end of an optical wave guides (9) or transfer piece to such an optical wave guide is located in the area of one or several of these focal points.

9. Appliance in accordance with claim 7, wherein the photocells are mounted on heat sinks (7) through which a liquid will be channeled.

10. Appliance in accordance with claim 7, wherein the photocells are mounted on heat sinks (7) through which gas with an operating pressure of >1 bar will flow.

11. Appliance in accordance with claim 9, wherein a thin-layered system of semi-conductors with a band gap of less than 0.7 eV is located between the photocells and the heat sinks (7).
